(19) United States
(12) Patent Application Publication
(10) Pub. No.: US 2017/0338361 A1
(43) Pub. Date: Nov. 23, 2017

(54) Flip-chip Multi-junction Solar Cell and Fabrication Method Thereof

(71) Applicant: XIAMEN SANAN OPTOELECTRONICS TECHNOLOGY CO., LTD., Xiamen (CN)

(72) Inventors: Weiping XIONG, Xiamen (CN); Jingfeng BI, Xiamen (CN); Wenjun CHEN, Xiamen (CN); Guanzhou LIU, Xiamen (CN); Meijia YANG, Xiamen (CN); Mingyang LI, Xiamen (CN); Chaoyu WU, Xiamen (CN); Duxiang WANG, Xiamen (CN)

(73) Assignee: XIAMEN SANAN OPTOELECTRONICS TECHNOLOGY CO., LTD., Xiamen (CN)

(21) Appl. No.: 15/669,922

(22) Filed: Aug. 5, 2017

Related U.S. Application Data
(63) Continuation of application No. PCT/CN2016/097759, filed on Sep. 1, 2016.

(30) Foreign Application Priority Data
Oct. 14, 2015 (CN) 201510659925.1

(51) Int. Cl. H01L 31/0443; H01L 31/048; H01L 31/0224; H01L 31/18; H01L 31/0687

(52) U.S. Cl. CPC H01L 31/0443; H01L 31/1892; H01L 31/0687; H01L 31/022433; H01L 31/022441; H01L 31/048

(57) ABSTRACT

A flip-chip multi junction solar cell chip integrated with a bypass diode includes from up to bottom: a glass cover; a transparent bonding layer; a front electrode; an n/p photoelectric conversion layer; a p/n tunnel junction; a structure layer of the n/p bypass diode; a first backside electrode; a second backside electrode. The solar cell chip also includes at least a through hole extending through the n/p photoelectric conversion layer, the p/n tunnel junction and the structure layer of the n/p bypass diode. An ultra-thin substrate-less cell can therefore be provided without occupying effective light receiving areas, greatly improving cell heat dissipation. With a light weight, the chip can also have advantages in space power application.

### CROSS-REFERENCE TO RELATED APPLICATIONS

The present application is a continuation of, and claims priority to, PCT/CN2016/097759 filed on Sep. 1, 2016, which claims priority to Chinese Patent Application No. 201510659925.1 filed on Oct. 14, 2015. The disclosures of these applications are hereby incorporated by reference in their entirety.

### BACKGROUND

Solar cells provide one of the important clean energy sources. Due to dispersity of sun light energy, a power system of certain size must have large number of solar cells in serial and parallel connection. The problem is that: if any solar cell fails, the generation power of the entire network will be sharply reduced. Meanwhile, the failed solar cell is equivalent to a load to form the so-called heat mark. Under long-term load, this failed solar cell will be irreversibly damaged, leading to irreversible efficiency attenuation, even failure of the entire network.

To solve this problem, a backside diode called bypass diode, is provided in parallel connection to every piece of the solar cell, which is reversed to the solar cell under normal working status, equivalent to open-circuit; when any solar cell fails and is not in working status, the bypass diode is in forward serial connection with adjacent solar cell, and breaks over under low voltage drop, thus guaranteeing normal operation of the entire network. However, on the one hand, the bypass diode makes cost high and package process complex; on the other hand, for non-condensing solar system, such as space application cell, as cells are arranged closely, the bypass diodes would take up a large portion of areas and reduce utilization of sun light. For condensing cell systems, in some systems that also require closely-arranged cells, such as electro-thermal combined production cell system, it is impossible to arrange a bypass diode for every solar cell. Today, in some solar batteries, the bypass diode is integrated on the solar cell, i.e., separating a portion from the solar cell to form the diode. This simplifies cell package process, and reduces radiation area occupied by the bypass diode. However, waste of radiation area cannot be completely solved by this solution. More importantly, this method is only applicable to circumstances with small photo current. The reason is that, let-through current of the bypass diode is in direct proportion to the p-n junction area. The larger is the photo current, the larger is the bypass diode. For example, in concentrator cell, the bypass diode would take up above 30% radiation area, which is absolutely not applicable.

### SUMMARY

To solve the above problem, various embodiments of the present disclosure provide a flip-chip multi junction solar cell integrated with a bypass diode and fabrication thereof. Both the bypass diode and the electrode are placed on the back side of the cell, which achieves zero-waste of effective radiation. In addition, as the bypass diode is on the non-light-receiving surface, there is no limit to the size of the area. This solves the problem that by-pass diode cannot be integrated on large-current cell.

According to a first aspect, a flip-chip multi junction solar cell chip integrated with a bypass diode is provided. The flip-chip multi junction cell chip comprises from up to bottom: a glass cover; a transparent bonding layer; a front electrode; an n/p photoelectric conversion layer; a p/n tunnel junction; a structure layer of the n/p bypass diode, wherein, the p-type layer is partially etched to expose part of the n-type layer; a first backside electrode that covers but goes no beyond the p-type layer of the bypass diode; a second backside electrode that covers but goes no beyond the exposed n-type layer of the bypass diode; the solar cell chip also comprises at least a through hole passing through the n/p photoelectric conversion layer, the p/n tunnel junction and the structure layer of the n/p bypass diode, wherein, inner walls of through-holes are deposited with an electrical insulation layer, and the through holes are filled with metals to connect the front electrode and the first backside electrode.

The flip-chip multi junction cell chip integrated with a bypass diode is characterized in that: the front electrode is a bar structure electrode and a main electrode is set at the position corresponding to the through holes, wherein, the main electrode covers and goes beyond through the through hole port, and the gate electrode of the bar structure electrode is connected to the main electrode.

The flip-chip multi junction cell chip integrated with a bypass diode is characterized in that: the n/p photoelectric conversion layer is a flip-chip multi junction cell structure, wherein, the n-type layer is the cell emitting region; the p-type layer is the cell base region; and the n/p photoelectric conversion layer also comprises a window layer on the upper surface of the n-type layer and a backfield layer on the bottom surface of the p-type layer; and the multi junction cells are connected in series through tunnel junctions.

The flip-chip multi junction cell chip integrated with a bypass diode is characterized in that: direction of the p-n junction of the structure layer of the n/p bypass diode is same as that of the n/p photoelectric conversion layer, wherein, the n-type layer is 1-5 μm thick, and the p-type layer is 50-100 nm thick.

The flip-chip multi junction cell chip integrated with a bypass diode is characterized in that: the p-type layer of the structure layer of the n/p bypass diode is partially etched, and the remaining p-type layer covers and goes beyond the through hole positions.

The flip-chip multi junction cell chip integrated with a bypass diode is characterized in that: after etching of the structure layer of the n/p bypass diode, size of the remaining p-type layer depends on the cell short circuit current, making let-through current density of the p-n junction of the bypass diode≦70 mA/mm².

The flip-chip multi junction cell chip integrated with a bypass diode is characterized in that: the first backside electrode covers but goes no beyond the p-type layer of the bypass diode; the first backside electrode covers and goes beyond the through hole position; and the first backside electrode and the p-type layer of the bypass diode form ohmic contact.

The flip-chip multi junction cell chip integrated with a bypass diode is characterized in that: an electrical insulation layer with thickness of 0.5-2 μm is deposited inside the through holes.

According to a second aspect, a fabrication method for a flip-chip multi junction solar cell chip integrated with a bypass diode is provided, comprising: providing an epitaxial wafer of flip-chip multi junction solar cell, comprising from bottom to up: an epitaxial substrate, an n/p photoelectric conversion layer, a p/n tunnel junction and a structure layer of the n/p bypass diode; etching part of the p-type layer of the bypass diode structure layer, and exposing part of the n-type layer; preparing a first and a second backside electrode through evaporation; temporarily bonding the above epitaxial wafer to the glass substrate; removing the epitaxial substrate; etching to form through holes, which pass through the n/p photoelectric conversion layer, the p/n tunnel junction and the structure layer of the n/p bypass diode; depositing an electrical insulation layer on the side wall of through holes; depositing a metal layer, which fills in to the inside of the through holes and forms the front electrode to realize electric connection between the front electrode and the first backside electrode; bonding the above solar cell to the glass cover with transparent adhesive; removing the temporary-bonding glass substrate.

The fabrication method of a flip-chip multi junction solar cell chip integrated with a bypass diode is characterized in that: the bonding medium is polymer, glass frit or low-melting-point metal.

The fabrication method of a flip-chip multi junction solar cell chip integrated with a bypass diode is characterized in that: the through holes are etched via ICP dry etching or chemical solution etching; the section of the through hole is circular or rectangle with the upper part wider than the lower part; the side wall is an inclined surface, facilitating deposition of the insulating layer and filling metal inside the through holes.

For concentrating solar cells, heat dissipation is an important topic. For space cell, thickness is a major parameter. In the solar cell chip provided by embodiments disclosed herein, the epitaxial substrate is completely removed. Heat generated by the cell photoelectric conversion layer is directly dissipated from the backside electrode, which greatly improves cell heat dissipation. On the other hand, the no-substrate design reduces cell weight to the maximum, being a prominent advantage in space cell application.

In another aspect, a solar power system is provided employing a plurality of multi junction solar cells described above.

### BRIEF DESCRIPTION OF THE DRAWINGS

FIG. 1 shows a flip-chip multi junction solar cell, comprising an epitaxial substrate, an n/p photoelectric conversion layer, a p/n tunnel junction and a structure layer of the n/p bypass diode.

FIG. 2 shows how to etch part of the p-type layer of the bypass diode and expose part of the n-type layer.

FIG. 3 shows how to deposit the first and second backside electrodes.

FIG. 4 shows how to temporarily bond the solar cell as shown in FIG. 3 to the glass substrate.

FIG. 5 shows how to remove the epitaxial substrate.

FIG. 6 shows how to form through holes at position corresponding to the remaining n-type layer of the bypass diode.

FIG. 7 shows how to deposit an electric insulation layer on the inner wall of through holes.

FIG. 8 shows how to fill in metal in the through holes and deposit a front electrode.

FIG. 9 shows how to bind the glass cover on the front surface of the solar cell.

FIG. 10 shows how to remove the temporary-bonding glass substrate and form a flip-chip multi junction solar cell chip integrated with a bypass diode.

FIG. 11 is a front top view showing a flip-chip multi junction solar cell chip integrated with a bypass diode.

FIG. 12 is a back top view showing a flip-chip multi junction solar cell chip integrated with a bypass diode.

FIG. 13 shows how to connect the flip-chip multi junction solar cell chips integrated with bypass diodes in series. If any one or several batteries has photoelectric conversion layer failed, current would circulate through the integrated bypass diode, without damaging the failed cell.

In the drawings: 001: epitaxial substrate; 002: n/p photoelectric conversion layer; 003: p/n tunnel junction; 004: n-type layer of the bypass diode structure; 005: p-type layer of the bypass diode structure; 006: first backside electrode; 007: second backside electrode; 008: temporary-bonding medium layer; 009: temporary-bonding glass substrate; 010: through-holes; 011: electrical insulation layer; 012: front electrode; 012a: front electrode main electrode; 012b: front electrode of the gate electrode; 013: filling metal in through-holes; 014: binder; 015: glass cover.

### DETAILED DESCRIPTION

Detailed description will be given to the realization of the present disclosure, which are not restrictive of the protection scope of the invention.

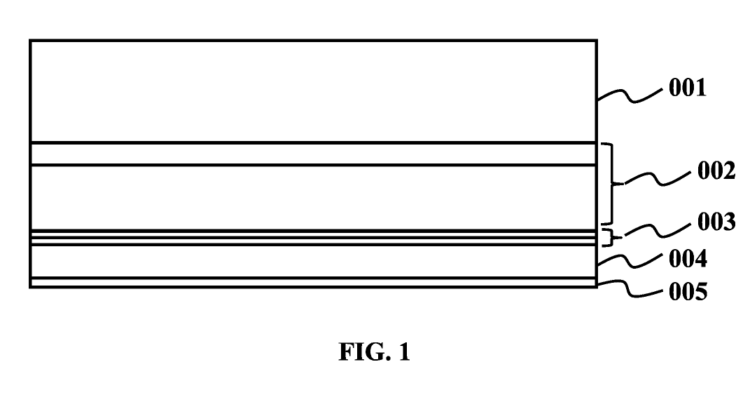

As shown in FIG. 1, provide an epitaxial wafer of flip-chip multi junction solar cell, comprising from bottom to up: an epitaxial substrate 001, an n/p photoelectric conversion layer 002, a p/n tunnel junction 003, an n-type layer 004 and a p-type layer 005 of the bypass diode structure, wherein, the n-type layer of the n/p photoelectric conversion layer 002 serves as the emitting region and grows on the epitaxial substrate 001; the p-type layer serves as the base region and grows on the n-type layer; the p/n tunnel junction 003 grows on the p-type layer of the photoelectric conversion layer 002, and the n-type layer 004 of the bypass diode grows on the p/n tunnel junction 003 with thickness of 3 nm; the p-type layer 005 of the bypass diode grows on the n-type layer 004 with thickness of 50 nm; and the photoelectric conversion layer 002 also comprises a window layer on the upper surface of the n-type layer and a backfield layer on the bottom surface of the p-type layer;

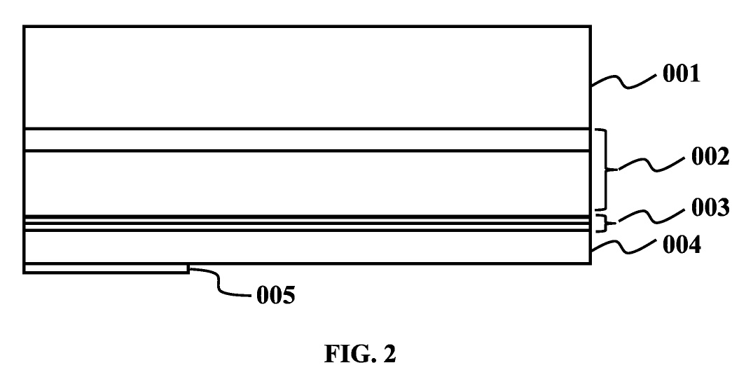

As shown in FIG. 2, etch the p-type layer 005 of the bypass diode structure layer and expose the n-type layer 004. The remaining p-type layer 005 is at one side of the solar cell. The length is equal to or slightly less than the side length of corresponding solar cell, depending on the photo current size, making let-through current density of the bypass diode≦70 mA/mm². In this embodiment, the width is 1 mm;

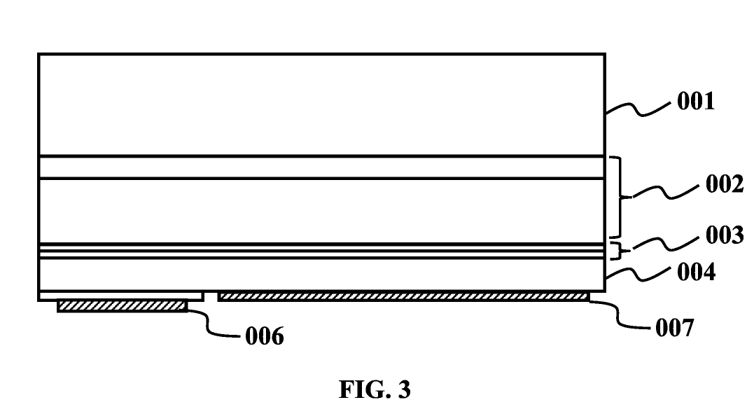

As shown in FIG. 3, form a first backside electrode 006 and a second backside electrode 007 on the backside of the above solar cell via photo-etching, electronic beam evaporation and striping-off, wherein, the first backside electrode 006 covers but goes no beyond the etched p-type layer 005 of the bypass diode, and the second backside electrode 007 covers but goes no beyond the exposed n-type layer 004 of the bypass diode after etching. In this embodiment, the first backside electrode 006 is 0.9 mm wide and 3 μm thick, and the second backside electrode 007 is 3 μm thick;

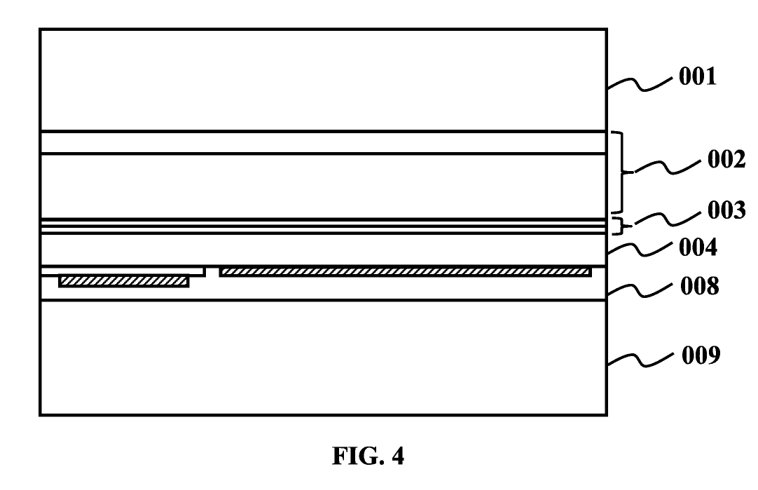

As shown in FIG. 4, temporarily bond the above solar cell to the glass substrate 009 taking polymer as the temporary-bonding medium layer 008;

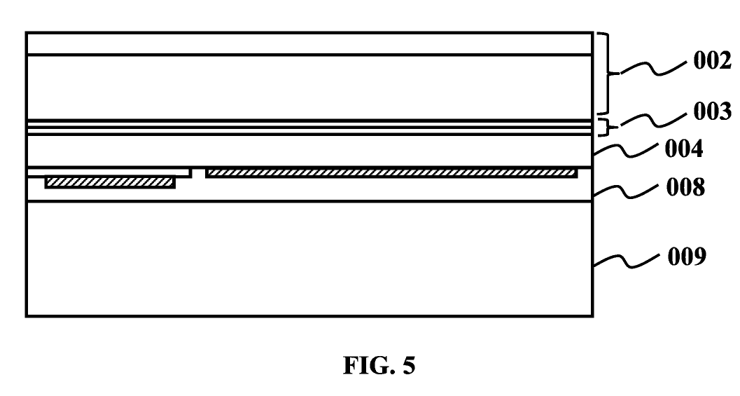

As shown in FIG. 5, remove the epitaxial substrate 001 via chemical corrosion;

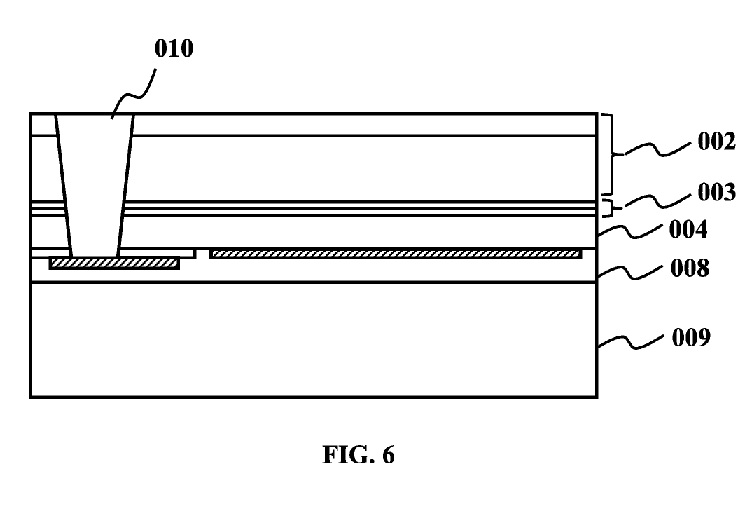

As shown in FIG. 6, form a plurality of through-holes 010 via chemical corrosion. The through-holes 010 are periodically arranged at the side of the etched p-type layer 005 of the bypass diode that is close to the solar cell outside. All through-holes 010 pass through the n/p photoelectric conversion layer 002, the p/n tunnel junction 003, the n-type layer 004 of the bypass diode structure layer and the p-type layer 005 of the bypass diode structure layer. In this embodiment, diameter of the through-hole 010 is 50 μm, and interval of adjacent through-holes is 1 mm. The side wall of the through-hole 010 is 50 μm far from the edge of the p-type layer 005 of the bypass diode;

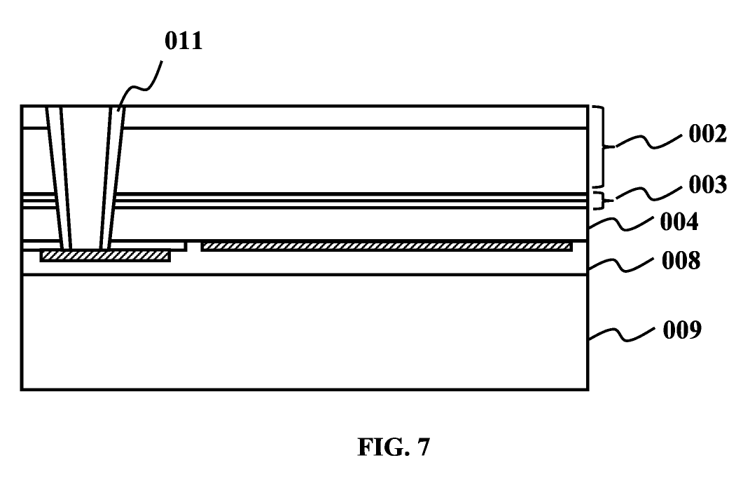

As shown in FIG. 7, deposit a silicon nitride insulation layer 011 with thickness of 1 μm on the inner wall of the through-holes 010 via PECVD, and remove the silicon nitride deposited on the first backside electrode 006;

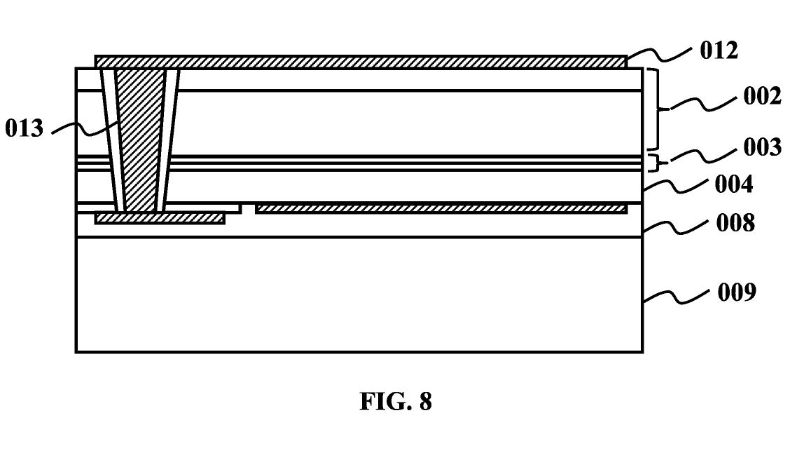

As shown in FIG. 8, evaporate a metal seed layer inside the through-holes 010 deposited with silicon nitride, then thicken the metal layer 013 inside the through-holes, until the through-holes 010 are fully filled in with metal. In this embodiment, the evaporated metal seed layer is Ti/Au, and electroplating metal is Cu; fabricate a front electrode 012 on the surface of the solar cell, comprising a main electrode 012a and a gate electrode 012b, wherein, the main electrode 012a is in strip-shape with width of 150 μm, which covers and goes beyond the through-holes 010, and its central line aligns with the center of the through-holes 010; the gate electrode 012b is a fine metal strip with parallel isometric arrangement, and is vertically connected to the main electrode 012a; anneal to form ohmic contact between the front electrode 012, the first backside electrode 006 and the second backside electrode 007 with the contacting semiconductor layer;

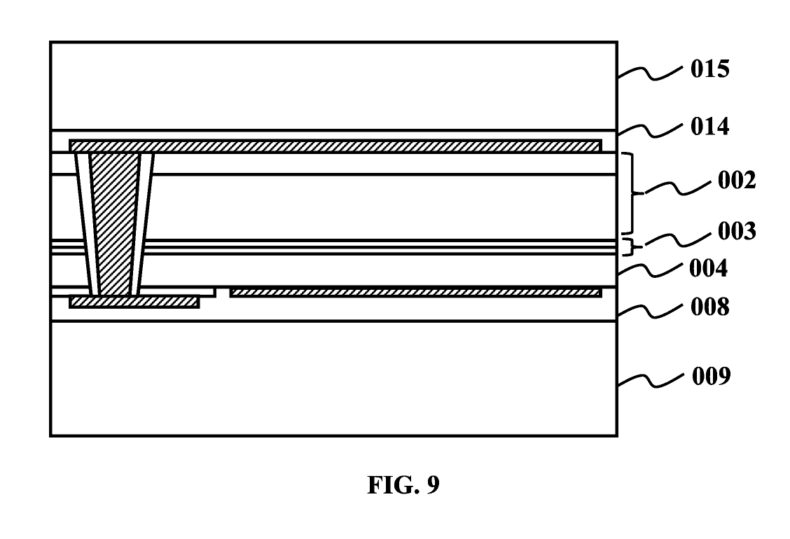

As shown in FIG. 9, bind a glass cover 015 on the front cover of the solar cell. In this embodiment, the adhesive 014 is silica gel and the glass cover is 100 μm thick;

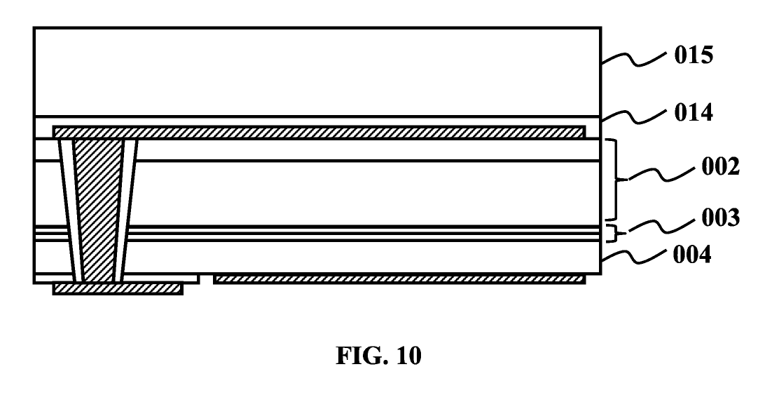

As shown in FIG. 10, remove the temporary-bonding glass substrate 009 and the temporary-bonding medium 008 to form a flip-chip multi junction solar cell chip integrated with a bypass diode;

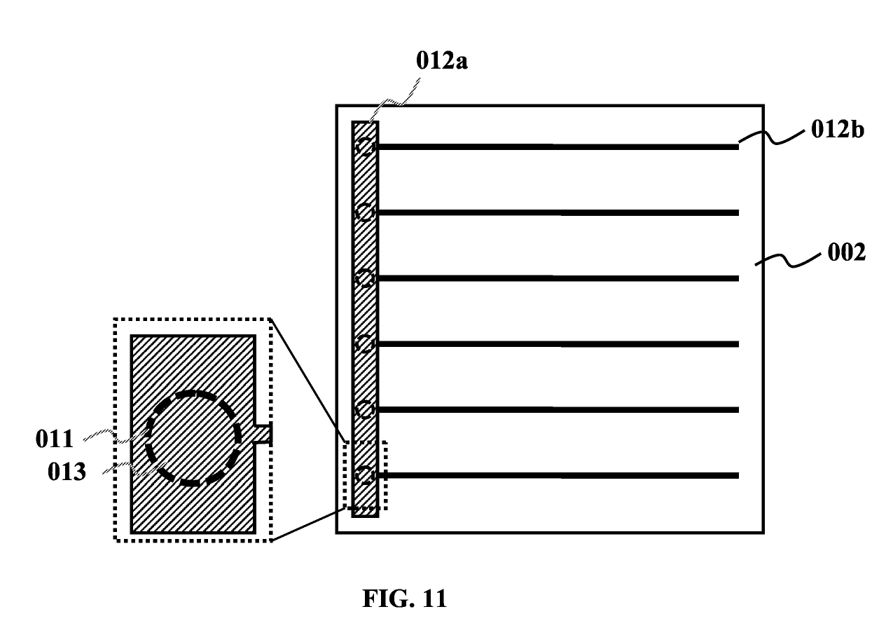

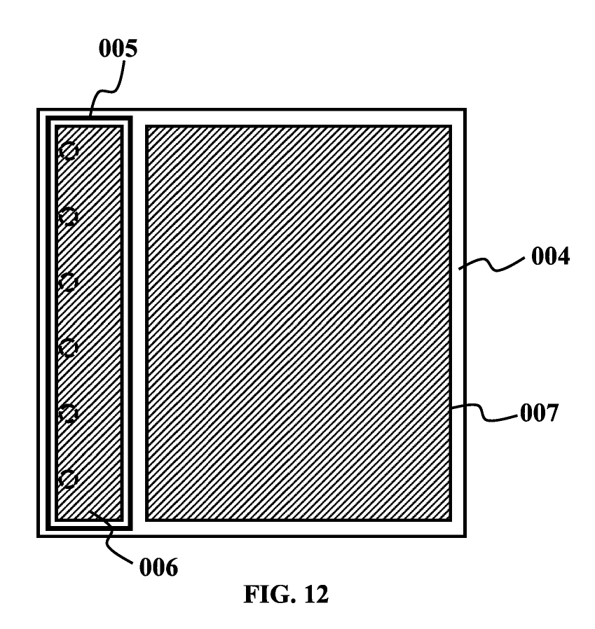

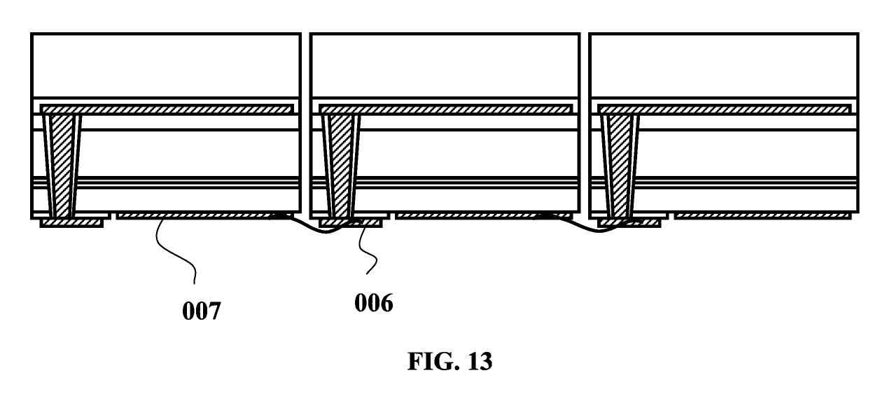

As shown in FIGS. 11-13, connect the first backside electrode 006 to the second backside electrode 007 of adjacent solar cell through a connecting band to achieve serial connection of solar cells. If any one or several batteries has photoelectric conversion layer failed, current would circulate through the integrated bypass diode, without damaging the failed cell.

All references referred to in the present disclosure are incorporated by reference in their entirety. Although specific embodiments have been described above in detail, the description is merely for purposes of illustration. It should be appreciated, therefore, that many aspects described above are not intended as required or essential elements unless explicitly stated otherwise. Various modifications of, and equivalent acts corresponding to, the disclosed aspects of the exemplary embodiments, in addition to those described above, can be made by a person of ordinary skill in the art, having the benefit of the present disclosure, without departing from the spirit and scope of the disclosure defined in the following claims, the scope of which is to be accorded the broadest interpretation so as to encompass such modifications and equivalent structures.

1. A flip-chip multi junction solar cell, comprising from bottom to up:
a glass cover;
a transparent bonding layer;
a front electrode;
an n/p photoelectric conversion layer;
a p/n tunnel junction;
a structure layer of an n/p bypass diode having a p-type layer partially etched to expose a portion of an n-type layer;
a first backside electrode that covers but without extending beyond the p-type layer of the bypass diode;
a second backside electrode that covers but without extending beyond the exposed n-type layer of the bypass diode; and
at least a through hole extending through the n/p photoelectric conversion layer, the p/n tunnel junction, and the structure layer of the n/p bypass diode, wherein an inner wall of a through-hole is deposited with an electrical insulation layer, and the through hole is filled with metals to connect the front electrode and the first backside electrode.

2. The solar cell of claim 1, wherein:
the front electrode is a bar-structure electrode;
a main electrode is at a position corresponding to the through holes;
the main electrode covers and extends beyond an end of the through hole; and
the gate electrode of the bar-structure electrode is connected to the main electrode.

3. The solar cell of claim 1, wherein:
the n/p photoelectric conversion layer is a flip-chip multi junction cell structure;
the n-type layer is a cell emitting region;
the p-type layer is a cell base region;
the n/p photoelectric conversion layer also comprises a window layer on an upper surface of the n-type layer and a backfield layer on a bottom surface of the p-type layer; and
the multi junction cell is connected in series through tunneling junctions.

4. The solar cell of claim 1, wherein:
direction of the p-n junction of the structure layer of the n/p bypass diode is same as that of the n/p photoelectric conversion layer; and
the n-type layer is 1-5 pm thick, and the p-type layer is 50-100 nm thick.

5. The solar cell of claim 1, wherein: the p-type layer of the structure layer of the n/p bypass diode is partially etched, and the remaining p-type layer covers and goes beyond the through hole positions.

6. The solar cell of claim 1, wherein: after etching of the structure layer of the n/p bypass diode, size of the remaining p-type layer depends on the cell short circuit current, making let-through current density of the p-n junction of the bypass diode≦70 mA/mm².

7. The solar cell of claim 1, wherein: the first backside electrode covers but goes no beyond the p-type layer of the bypass diode; the first backside electrode covers and goes beyond the through hole position; and the first backside electrode and the p-type layer of the bypass diode form ohmic contact.

8. The solar cell of claim 1, wherein: an electrical insulation layer with thickness of 0.5-2 μm is deposited inside the through holes.

9. A fabrication method of the flip-chip multi junction solar cell of claim 1, the method comprising:
providing an epitaxial wafer of flip-chip multi junction solar cell, comprising from bottom to up:
an epitaxial substrate;
an n/p photoelectric conversion layer; and
a p/n tunnel junction and a structure layer of the n/p bypass diode;
etching part of the p-type layer of the bypass diode structure layer, and exposing a portion of the n-type layer;
preparing a first and a second backside electrode through evaporation;
temporarily bonding the above epitaxial wafer to the glass substrate;
removing the epitaxial substrate;
etching to form through holes, which pass through the n/p photoelectric conversion layer, the p/n tunnel junction and the structure layer of the n/p bypass diode;
depositing an electrical insulation layer on the side wall of through holes;
depositing a metal layer, which fills in to the inside of the through holes and forms the front electrode to realize electric connection between the front electrode and the first backside electrode;
bonding the above solar cell to the glass cover with transparent adhesive; and
removing the temporary-bonding glass substrate.

10. The method of claim 9, wherein: the epitaxial substrate was removed via chemical corrosion.

11. The method of claim 9, wherein: the silicon nitride insulation layer with thickness of 1 μm was deposited on the inner wall of the through-holes via PECVD.

12. The method of claim 9, wherein: the evaporated metal seed layer is Ti/Au, and an electroplating metal is Cu.

13. The method of claim 9, wherein: a length of the remaining p-type layer is equal to or slightly less than the side length of corresponding solar cell, depending on the photo current size.

14. The method of claim 9, wherein: the through-holes are periodically arranged at the side of the etched p-type layer of the bypass diode that is close to the solar cell outside.

15. The method of claim 9, wherein: the ohmic contact between the front electrode, the first backside electrode and the second backside electrode with the contacting semiconductor layer is formed by annealing.

16. The method of claim 9, wherein: the bonding medium is polymer, glass frit or low-melting-point metal.

17. The method of claim 9, wherein: the through holes are etched via ICP dry etching or chemical solution etching; the section of the through hole is circular or rectangle with the upper part wider than the lower part; the side wall is an inclined surface, facilitating deposition of the insulating layer and filling metal inside the through holes.

18. A solar power system comprising a plurality of flip-chip multi junction solar cells, each cell comprising from bottom to up:
a glass cover;
a transparent bonding layer;
a front electrode;
an n/p photoelectric conversion layer;
a p/n tunnel junction;
a structure layer of an n/p bypass diode having a p-type layer partially etched to expose a portion of an n-type layer;
a first backside electrode that covers but without extending beyond the p-type layer of the bypass diode;
a second backside electrode that covers but without extending beyond the exposed n-type layer of the bypass diode; and
at least a through hole extending through the n/p photoelectric conversion layer, the p/n tunnel junction, and the structure layer of the n/p bypass diode, wherein an inner wall of a through-hole is deposited with an electrical insulation layer, and the through hole is filled with metals to connect the front electrode and the first backside electrode.

19. The system of claim 18, wherein:
the front electrode is a bar-structure electrode;
a main electrode is at a position corresponding to the through holes;
the main electrode covers and extends beyond an end of the through hole; and
the gate electrode of the bar-structure electrode is connected to the main electrode.

20. The system of claim 18, wherein:
the n/p photoelectric conversion layer is a flip-chip multi junction cell structure;
the n-type layer is a cell emitting region;
the p-type layer is a cell base region;
the n/p photoelectric conversion layer also comprises a window layer on an upper surface of the n-type layer and a backfield layer on a bottom surface of the p-type layer; and
the plurality of multi junction cells are connected in series through tunneling junctions.
